(19) United States
(12) Patent Application Publication
(10) Pub. No.: US 2011/0088743 A1
(43) Pub. Date: Apr. 21, 2011

(54) METHOD TO MANAGE A PHOTOVOLTAIC SYSTEM

(76) Inventors: Yuhao Luo, San Jose, CA (US); Zhi-min Ling, Cupertino, CA (US)

(21) Appl. No.: 12/904,972

(22) Filed: Oct. 14, 2010

Related U.S. Application Data
(60) Provisional application No. 61/336,200, filed on Jan. 19, 2010.
(60) Provisional application No. 61/279,130, filed on Oct. 15, 2009.

(51) Int. Cl. H01L 31/042

(52) U.S. Cl. 136/244

(57) ABSTRACT

An apparatus and method relates to managing and controlling a photovoltaic system, especially for the safety, maintenance, alert of theft, and connection failure of the system. It is more specially for cases during the night time when the panel is not generating electricity. The present disclosure provides: an AC panel, an inverter; a communication circuit in a panel inverter to send and receive signals, a control circuit, a communicator and a power line communication method between communicator and panel inverters. The communicator detects an identification of each panel to identify the panels and collect data from each panel. The communicator is connected to the Internet through a web gateway. The apparatus also has a web based managing system to collect data from the communicator, as well as transmit signals to the communicator.

### CROSS REFERENCE TO RELATED PATENT APPLICATIONS

The instant patent application converts and claims priority to U.S. Provisional Patent Application No. 61/336,200 filed on Jan. 19, 2010 to Luo et al., entitled “A Method of Managing a Photovoltaic System” which is herein incorporated by reference in its entirety. The instant patent application also converts and claims priority to U.S. Provisional Patent Application No. 61/279,130 filed on Oct. 15, 2009 to Luo, entitled “Detecting Fault in Solar Panel and Inverter” which is herein incorporated by reference in its entirety.

### FIELD OF THE INVENTION

The present disclosure relates to a method of managing and controlling a photovoltaic system. More particularly, the present disclosure includes a controller to control the panels especially for safety, maintenance, security and failure of the system.

### BACKGROUND OF THE RELATED ART

Producing power from solar energy involves installing multiple solar panels and transforming the sun's rays into electricity. Over time, the solar panels and inverters tend to become faulty due to various factors. For example, shading, snow or dust cause fault of the panels' productivity. A faulty inverter may also impair a solar array's power and productivity. As result, a solar panel and inverter requires constant monitoring and maintenance to ensure normal operation. Also, the solar panel may be stolen and removed from operation.

In general, detecting and correcting a fault of a solar panel and inverter in a solar array can be a very complicated. This particularly occurs when the array has large amount of solar panels. It is even more complicated to locate and identify the type of fault without a physical inspection, which is very costly. There are solutions of detecting fault of array by comparing operation profile with stored reference profile. However, the operation profile is strongly depending on many conditions, such as time, season and climate, which can affect the detection. Due to the complexity of these numerous conditions, the need of reference profiles and the need of generating reference profiles, as well as the comparison with parameters with reference profiles, this process can be very complicated and the result could be inaccurate.

Accordingly, there exists a need for a method and apparatus to conveniently, quickly, and accurately manage a solar panel and solar array from a remote location and that prevents theft of components of a system.

### SUMMARY OF THE INVENTION

It is the object of the present disclosure to find a low cost monitoring and control method for photovoltaic system with panel inverters, more specifically for safety control, theft and failure detection. It is more specially for cases during the night time when the panel is not generating electricity.

The disclosure relies on the several factors:

1. Each panel has an inverter, which is named panel inverter here.

2. Panel inverter is attached to panel so tight that any separation will damage the panel. E.g. panel inverter is attached to the back surface of the panel by adhesive; inverter is attached to panel frame by rivets. The combination of panel and panel inverter is named AC panel.

3. There are 2 output AC cables for each AC panel, but connected inside of inverter. Each AC cable has multiple wires inside. The wires are connected together inside inverter. The output of power conversion circuit is connected to the output wires.

4. There is communication circuit inside panel inverter, which is connected to output cables to send and receive signals. Communication circuit also send signal to control circuit.

5. In a photovoltaic system, the outputs of panel inverters are connected in series and then to AC power line, electric panel, and AC outlet.

6. A communicator is plugged into AC outlet.

7. Data is transferred between communicator and panel inverters through a power line communication method.

8. The communicator detects ID of each panel to identify them and collect data from each panel.

9. The communicator is connected to internet through web gateway. Web based managing system collect data from communicator, as well as send signal to the communicator.

10. The communicator can send signal through power line to all panel inverters to communication circuit and then control circuit.

When there is a need to maintain solar system, user can input command in the web system, the system will send a command to data communicator, which will send a signal to panel inverter control circuit to stop the operation of the inverter. As result, even though solar panel is still generating DC power, there is no AC current/voltage output from the inverter. It is safe for people to approach or maintain the system.

When there is a theft, as the panel inverter is attached to panel solidly with anti-theft method, they have to disconnect the panel inverter from the cables. Since the AC cables are connected in series to form the power line, the disconnection breaks the power line. As each panel and inverter communicate with communicator power line, the break will terminate the data communication from all panels beyond it. The managing system will detect and localize the open, send signal to alarm, show alert message, or send alert to any mobile devices.

This feature works the same way when there is failure in cable connection, which is one of most popular failure modes.

According to a first aspect of the present disclosure, there is provided a method of detecting a parameter in a solar panel array. The method comprises providing a first signal from a first solar panel to a remote entity with the first solar panel being connected to a second solar panel and providing a second signal from the second solar panel to the remote entity. The method infers that at least one solar panel has been removed from the array when at least one of the first or second signal is interrupted to the remote entity.

In yet another aspect of the present disclosure there is provided an apparatus for detecting a parameter of a solar panel array comprising a first solar panel providing a first signal from the first solar panel to a remote entity. The first solar panel is connected to a second solar panel. The second solar panel provides a second signal from the second solar panel to the remote entity. The apparatus also has a device connected to the first and the second solar panel. The device infers that at least one solar panel has been removed from the array when at least one of the first or second signal is interrupted to the device.

In another embodiment of the present disclosure, there is provided a method of safely shutting down operation of a solar panel array comprising providing a first solar panel connected to a first inverter. The first inverter comprises at least one of a control circuit, a power conversion circuit, a monitoring circuit and a communication circuit. The method provides a second solar panel connected to a second inverter with the second inverter comprising at least one of the control circuit, the power conversion circuit, the monitoring circuit and the communication circuit. The method provides a managing system connected to the first and the second solar panels. The method controls at least one component of the first or the second inverter to shut down operation of the solar panel array.

According to yet another embodiment of the present disclosure there is provided a safety device comprising a first solar panel being connected to a first inverter with the first inverter comprising at least one of a control circuit, a power conversion circuit, a monitoring circuit and a communication circuit. The device also has a second solar panel connected to a second inverter with the second inverter comprising at least one of the control circuit, the power conversion circuit, the monitoring circuit and the communication circuit. The device also has a managing system connected to the first and the second solar panels. The managing system controls at least one component of the first or the second inverter to shut down operation of the solar panel array.

According to another aspect of the present disclosure, there is provided an inverter comprising: a control circuit, a power conversion circuit, a monitoring circuit and a communication circuit, the communication circuit providing a signal to a remote entity, wherein the remote entity infers a condition when the signal is interrupted.

### BRIEF DESCRIPTION OF THE FIGURES

The foregoing and other objects, features and advantages of the disclosure will be apparent from the following more particular description of preferred embodiments of the disclosure, as illustrated in the accompanying drawings in which like reference characters refer to the same parts throughout different views. The drawings are not meant to limit the disclosure to particular mechanisms for carrying out the disclosure in practice, but rather, are illustrative of certain ways of performing the disclosure. Others will be readily apparent to those skilled in the art.

FIG. 1A shows an illustration of a photovoltaic DC panel 100;

FIG. 1B shows an illustration of a photovoltaic panel inverter 100′;

FIG. 1C shows an illustration of a photovoltaic AC panel 100″, comprising of DC panel 100 and panel inverter 100′;

FIG. 2 is a block diagram of a photovoltaic panel inverter;

FIG. 3 shows an illustration of a photovoltaic system, comprising AC panel, AC cable, electric panel, AC outlet, power line, communicator, web gateway and managing system;

FIG. 4 shows an illustration of a safety feature of the photovoltaic system;

FIG. 5 shows an illustration of the data communication flow of the photovoltaic system when the panel inverters send data to the web managing system; and

FIG. 6 shows an illustration of feature to monitoring the theft or open failure of cable connections.

### DETAILED DESCRIPTION OF THE PREFERRED EMBODIMENTS

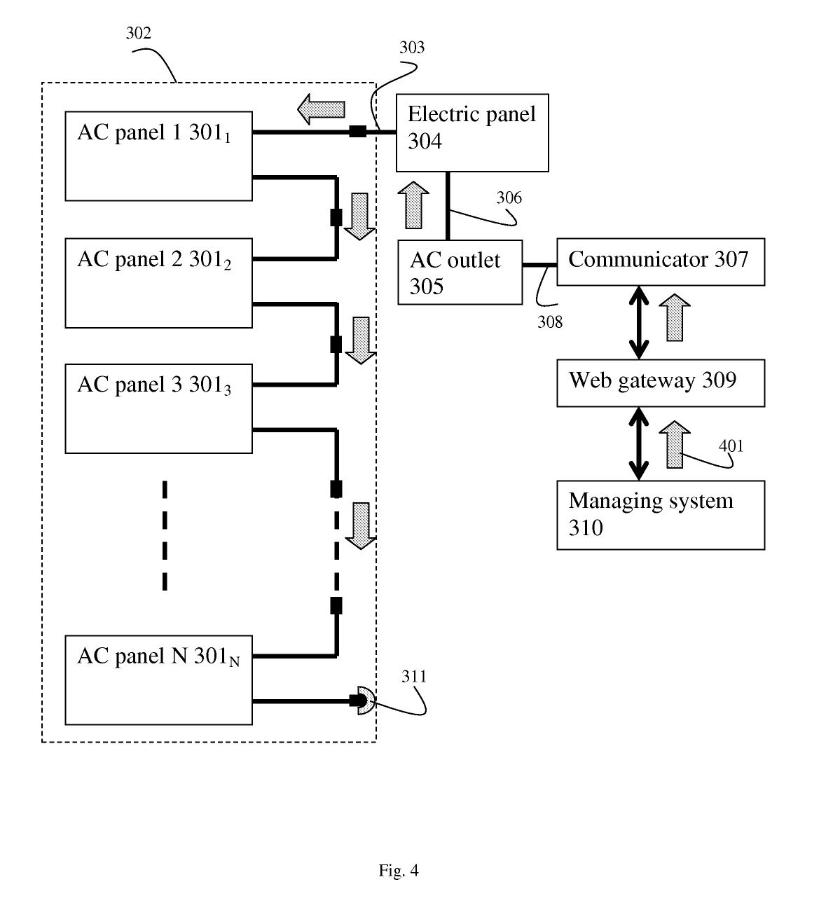

The present disclosure provides a method of detecting a parameter in a solar panel array 3011, 3012, and 3013 (FIG. 4). The method comprises providing a first signal from a first solar panel 3011 to a remote entity 310 with the first solar panel 3011 being connected to a second solar panel 3012 and providing a second signal from the second solar panel 3012 to the remote entity 310. The method infers that at least one solar panel 3011 or 3012 has been removed from the array when at least one of the first or second signal is interrupted to the remote entity 310 as shown in FIG. 4 and as will be discussed herein. The remote entity 310 can control an alarm or the like or otherwise control the array or can control components that control components of the array to perform various advantageous functions. Also in another embodiment, the remote entity 310 can perform an emergency shut down procedure when needed.

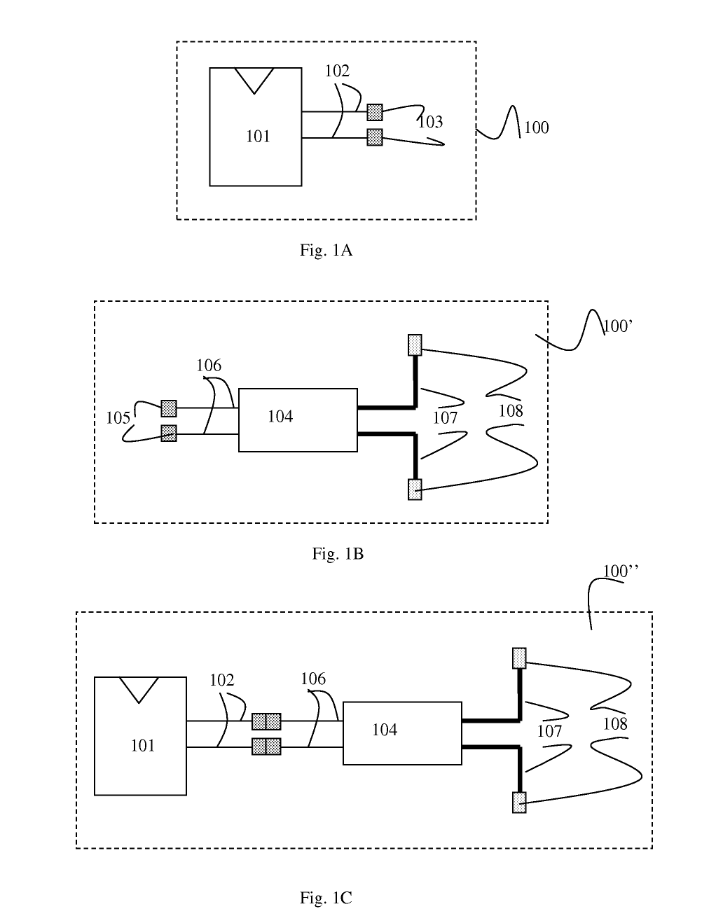

FIG. 1 shows an illustration of a photovoltaic DC panel 100, comprising of panel 101 with plurality of solar cells, DC cables 102, and connectors 103. The panel 101 of the solar cells is electrically connected to DC cables 102 and connectors 103 as shown. It should be appreciated that the panel 101 may comprise at least one solar cell, two solar cells or more than two solar cells and various configurations are possible and within the scope of the present disclosure.

FIG. 1B shows an illustration of a photovoltaic panel inverter 100′, comprising of input DC cables 106, input cables DC connectors 105, inverter 104, output AC cables 107, and AC cable connectors 108. Preferably, the DC input cable connectors 105 are connected to the input DC cables 106, which are connected to the inverter 104. Inverter 104 is connected to output DC cables 107, which are connected to the AC cable connector 108. It should be appreciated that the configuration of the inverter panel 100′ is not limiting and the present panel 100′ may include a different configuration than shown herein.

FIG. 1C shows an illustration of a photovoltaic AC panel 100″, comprising of DC panel 100 and panel inverter 104. The connectors 103 of DC panel 100 of FIG. 1A and input connectors 105 of FIG. 1B of panel inverter 104 are connected together as shown in FIG. 1C. FIG. 1C shows the panel 101 being connected to DC cables 102, which are connected to connectors 103, which are connected to DC input cable connectors 105. DC input cable connectors 105 are connected to input DC cables 106, which are connected to the panel inverter 104, which are connected to the output DC cables 108 and which are then connected to AC cable connector 108. It should be appreciated that the configuration of the DC panel 100″ is not limiting and the present panel 100″ may include a different configuration than shown herein.

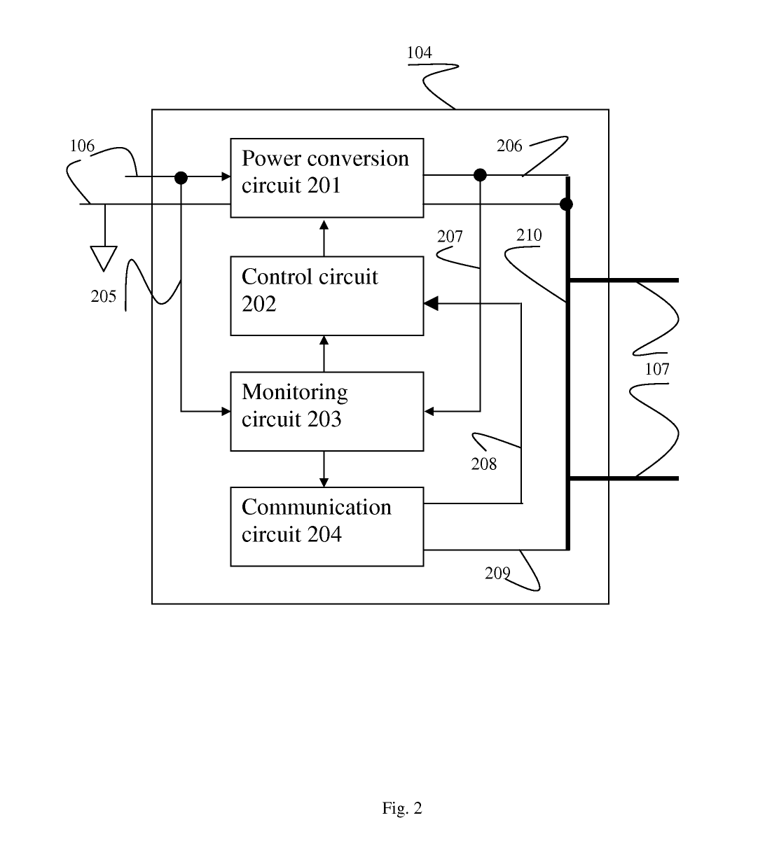

FIG. 2 is a block diagram of a photovoltaic panel inverter 104 shown in FIGS. 1B and 1C. Inverter 104 is connected to input DC cable 106. The inverter 104 includes, but not limited to: a power conversion circuit 201, a control circuit 202, a monitoring circuit 203, and a communication circuit 204.

The power conversion circuit 201 converts DC current from input DC cable 102 shown in FIG. 1C into AC current at output 206. The power conversion circuit 201 is connected to terminal 210 through an output 206. The monitoring circuit 203 monitors signals at a DC input through an input 205. The monitoring circuit 203 monitors signals such as current, and voltage via input 205. The monitoring circuit 203 monitors signals at an AC output through an output 207, such as current, voltage, frequency, etc. The monitoring circuit 203 sends data to the communication circuit 204. The communication circuit 204 is connected to a terminal 210 through a communication path 209 (wired path or wireless path via an RF element). The terminal 210 is connected to the output cables 107 of inverter 104. The communication circuit 204 communicates data out of inverter 104 though the path 209, the terminal 210, and the output cables 107.

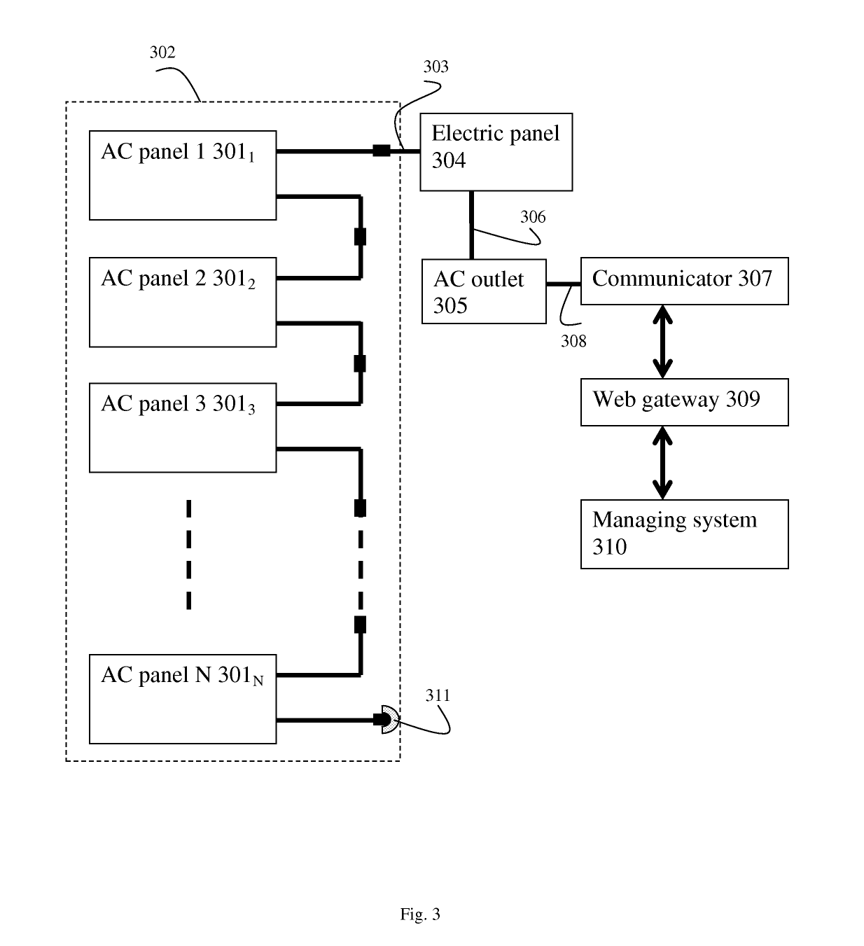

FIG. 3 shows an illustration of a photovoltaic system, comprising AC panel 301, AC cable 303, the electric panel 304, an AC outlet 305, a power line 306, a communicator 307, a web gateway 309 and a managing system 310. Preferably, the AC panel 301 is connected to the AC cable 303. AC cable 303 is connected to the electric panel 304, which is connected to the power line 306. Power line 306 is connected to the AC outlet 305, which is connected to a line 308. Line 308 is connected to the communicator 307. Communicator 307 includes a bidirectional communication path to the web gateway 309, which also has a bidirectional communication path to the managing system 310.

A plurality of AC panels 3011, 3012, 3013 . . . 301N are connected in series by connecting the AC cable connectors 108 to form a string generally represented by reference numeral 302. Preferably, AC panel 3011 is connected to AC panel 3012 and so on. Due to the connection method of the AC cable 107 shown in FIG. 2 and the power conversion circuit output 206 shown in FIG. 2, for the string 302 of AC panels 301 (shown in FIG. 3), the power conversion circuit outputs 206 (FIG. 2) are connected into the AC cable 303 (FIG. 3) in parallel.

One end of the AC cable 303 of the string is connected into the electric panel 304 through the AC cable 303, and the AC outlets 305 through power line 306. At the other end of the string, the cable connector is covered by a cap 311 as protection and insulation.

Turning now again to FIG. 3, a communicator 307 is shown. Communicator 307 is shown plugged into the AC outlet 305 through the power cord 308. By a power line communication method, the communicator 307 communicates with the AC panel 301 through the power cord 308, the electric panel 304, the AC outlet 305, the power line 306, and the AC cables 107 shown in FIG. 2. The communicator 307 is also connected to the web gateway 307 by an Ethernet connection, Wi-Fi, Wi-Max, Bluetooth™, or via other wireless, or similar methods known in the art. Through the web gateway 309, a web based managing system 310 collects the system information from the communicator 307 and perform storage, analysis, presenting, graphing, and other functions. Managing system 310 also sends a signal to communicator 307 and then to the AC panels 3011, 3012, etc.

FIG. 4 shows an illustration of a safety feature of the photovoltaic system. When user wants to maintain or wants to quickly shutdown the system for an emergency the AC panel will still generate AC voltage and current, which causes risks to the person approaching the system. This occurs even if grid connection is shut off by electric panel 304, and if there is sun on the panel, then the AC panel will still generate AC voltage and current, which causes risks to the person approaching the system. The present disclosure introduces a safety feature to shutdown panels, which is advantageous.

A command is input from managing system 310. The signal 401 is transferred through the web gateway 309, the communicator 307, the power cord 308, the AC outlet 305, and the power line 306. The signal 401 shown by arrow will then traverse to the electric panel 304, the AC cable 303, and the panel AC cables 107 shown in FIG. 2 into AC panel 301. The communication circuit 204 in the panel inverter 104 (FIG. 2) receives the signal through the path 209 (FIG. 2) and sends a signal through the path 208 (FIG. 2) to the control circuit 202 (FIG. 2) to shut down the power conversion circuit 201 (FIG. 2) and then the output 206 (FIG. 2) of the AC panel 301 (FIG. 4). This feature eliminates the danger of exposure to a high voltage AC for maintenance person, users, servicers, police, and fireman, etc. It should be appreciated that in an alternative embodiment, the communication circuit 204 may receive the signal via a different wireless or wired method than shown herein. For example, using a transceiver or the like the managing system 310 of FIG. 4 may directly communicate with the communication circuit 204 of FIG. 2 or some of the elements shown may be eliminated and connected differently.

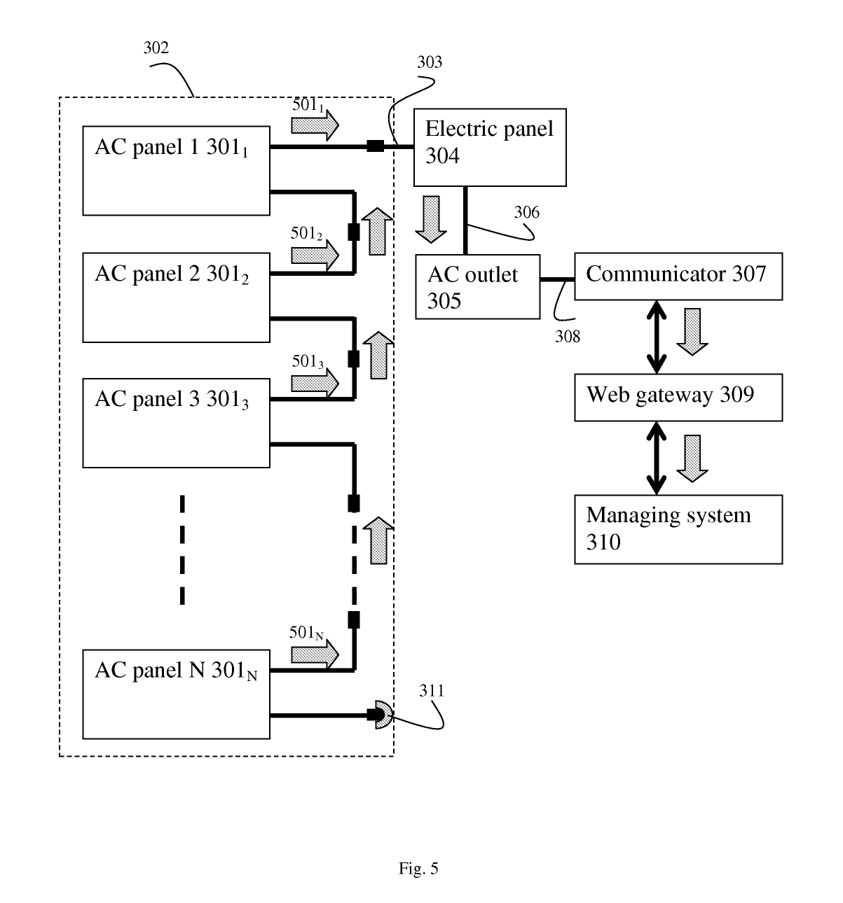

FIG. 5 shows an illustration of the data communication flow of the photovoltaic system when the panel inverter(s) 104 (FIG. 2) send data to the web managing system 310 (FIG. 5). It should be appreciated that the number of inverters 104 sending data can be one inverter 104 or more than one inverter 104 and various configurations are possible and within the scope of the present disclosure. The monitoring circuit 203 (FIG. 2) in panel inverter 104 (FIG. 2) collects data, such as current, voltage, frequency, temperature, etc, and sends the signal to communication circuit 204 (FIG. 2) in the inverter 104 (FIG. 2). The communication circuit 204 (FIG. 2) sends the data 501 (FIG. 5) through the AC panel cables 107 (FIG. 2) into the string AC cable 303 (FIG. 5) and then into electric panel 304 (FIG. 5). The signal shown by arrow is then communicated through the power line 306 (FIG. 5) into the AC outlet 305 (FIG. 5). The data then passed into the communicator 307 (FIG. 5) through the power cord 308 (FIG. 5). The communicator 307 (FIG. 5) sends the data to the web gateway 309 (FIG. 5), and then into the internet based managing system 310 (FIG. 5).

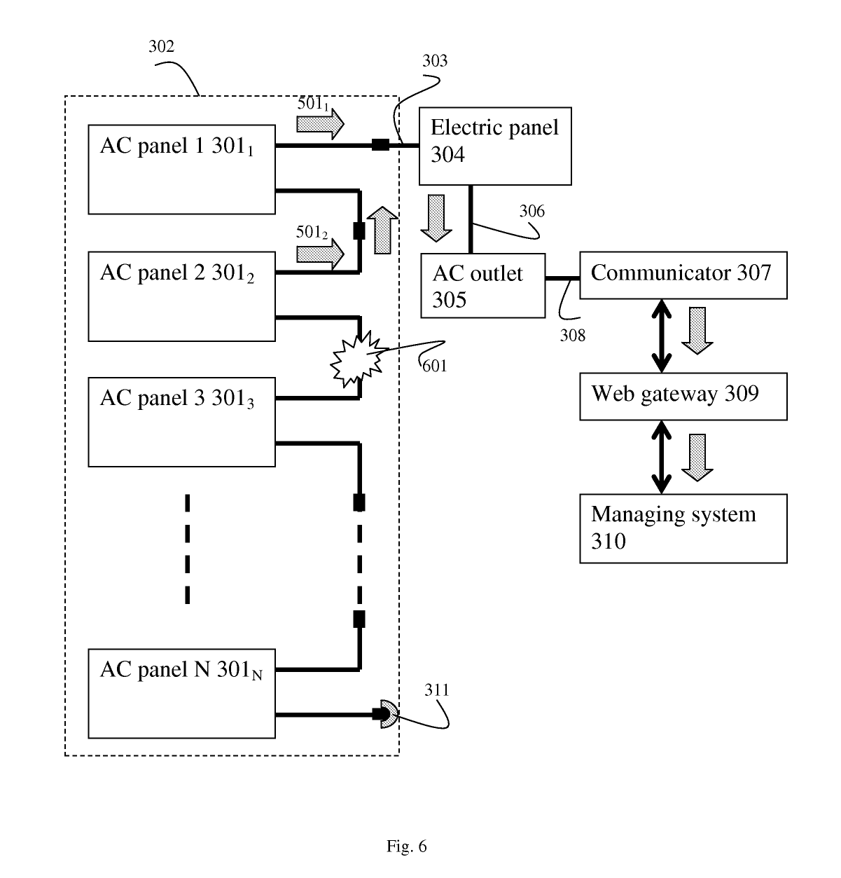

FIG. 6 shows an illustration of the feature to monitor the theft or to monitor the failure or otherwise removal of one component of the system. The component preferably can be a solar panel 101 as shown in FIG. 1A or can be any component of the system and is not limited to the solar panel 101. As an example, when the AC cable connection between the AC panel 3012 and the AC panel 3013 is broken as shown as break 601 due to theft or due to a part failure, the data communication flow of the photovoltaic system stops at the panel 3012 and the AC panel 3013 does not communicate along the break 601. As the managing system 310 (FIG. 6) monitors the data from each individual AC panel 3011, 3012, 3013, and 301n (FIG. 6), when the managing system 310 (FIG. 6) only receives data as shown by arrow 5011 managing system 310 (FIG. 6) from the AC panel 3011 and data as shown by arrow 5012 from the AC panel 3012, and when the managing system 310 does not receive data that it usually would receive from elements 3013 and 3013n in the form of arrows 5013- to 501N not shown, the managing system 310 infers that there is a break between the AC panel 3012 and the AC panel 3013 (FIG. 6). The managing system 310 (FIG. 6) will turn on an alarm, or show an alert message, or even send an alarm to mobile devices. The managing system 310 (FIG. 6) preferably provides some audible alarm to indicate the removal of the component. This managing system 310 (FIG. 6) feature works even when the panels 3011 through 301N are not generating electricity, such as during night time hours or even when the panels 3011 through 301N covered.

In a less preferable embodiment of the present disclosure, the solar panels may not provide a continuous signal to the managing system 310. In this less preferable embodiment, a signal from a solar panel inverter 104 may only be provided when a solar panel next to the removed solar panel is removed to the managing system 310. In this instance, the managing system 310 would infer that the adjacent solar panel has been removed upon receiving the signal.

Referring again to FIGS. 1-6 certain aspects of the system and components thereof may be implemented on a computer system. The computer system preferably includes the generic components of most general purpose computers. The computer system comprises an interconnection mechanism such as a bus or circuitry which couples an input device such as a keyboard. The system also has a processor (such as a microprocessor having an arithmetic logic unit, a register and a control unit). The computer also includes a storage device or memory (such as a computer disk for a main memory and secondary storage) and an output device such as a monitor or screen. The computer also has a network connection for connecting to the Internet. Various embodiments of the disclosure will be described in conjunction with the components of computer systems. A typical example of a computer system is an IBM® Personal Computer, an APPLE® MAC® computer, or a compatible computer.

Generally, in operation, the computer system operable with that method shown in FIGS. 1-6 is controlled by an operating system. Typical examples of operating systems are MS-DOS and Windows95 from Microsoft Corporation, or Solaris and SunOS from Sun Microsystems, Inc., or the Apple OSX from Apple Corporation. As the computer system operates, input such as input search data, database record data, programs and commands, received from users or other processing systems, are stored on storage device. Certain commands cause the processor to retrieve and execute the stored programs. The programs executing on the processor may obtain more data from the same or a different input device, such as a network connection. The programs may also access data in a database for example, and commands and other input data may cause the processor to index, search and perform other operations on the database in relation to other input data. Data may be generated which is sent to the output device for display to the user or for transmission to another computer system or device. Typical examples of the computer system are personal computers and workstations, hand-held computers, dedicated computers designed for a specific purpose, and large main frame computers suited for use many users. The present disclosure is not limited to being implemented on any specific type of computer system or data processing device.

It is noted that the present disclosure may also be implemented in hardware or circuitry which embodies the logic and processing disclosed herein, or alternatively, the present disclosure may be implemented in software in the form of a computer program stored on a computer readable medium such as a storage device. In the later case, the present disclosure in the form of computer program logic and executable instructions is read and executed by the processor and instructs the computer system to perform the functionality disclosed as the disclosure herein. If the present disclosure is embodied as a computer program, the computer program logic is not limited to being implemented in any specific programming language. For example, commonly used programming languages such as C, C++, JAVA as well as others may be used to implement the logic and functionality of the present disclosure. Furthermore, the subject matter of the present disclosure is not limited to currently existing computer processing devices or programming languages, but rather, is meant to be able to be implemented in many different types of environments in both hardware and software.

Furthermore, combinations of embodiments of the disclosure may be divided into specific functions and implemented on different individual computer processing devices and systems which may be interconnected to communicate and interact with each other. Dividing up the functionality of the disclosure between several different computers is meant to be covered within the scope of the disclosure.

While this disclosure has been particularly shown and described with references to a preferred embodiment thereof, it will be understood by those skilled in the art that is made therein without departing from the spirit and scope of the disclosure as defined by the following claims.

What is claimed is:

1. A method of detecting a parameter in a solar panel array comprising:
providing a first signal from a first solar panel to a remote entity;
the first solar panel being connected to a second solar panel;
providing a second signal from the second solar panel to the remote entity; and
inferring that at least one solar panel has been removed from the array when at least one of the first or second signal is interrupted to the remote entity.

2. The method of claim 1, further comprising connecting a first inverter to the first solar panel and a second inverter to the second solar panel.

3. The method of claim 2, further comprising providing a circuit being connected to monitor an input of the first and the second inverter.

4. The method of claim 3, further comprising monitoring the input of the first and the second inverter for at least one of a power signal, a voltage or a current signal.

5. The method of claim 4, further comprising detecting that the input has been interrupted and inferring that the solar panel has been removed.

6. The method of claim 5, further comprising providing a computing device being connected to the first and the second solar panel, and the computing device inferring that at least one solar panel has been removed from the array when at least one of the first or second signal is interrupted.

7. The method of claim 1, further comprising providing more than two solar panels with each solar panel providing a respective signal to the remote entity.

8. The method of claim 7, further comprising inferring that at least one solar panel has been removed from the array when at least one signal from the more than two solar panels is interrupted.

9. The method of claim 1, further comprising providing a managing system comprising a processor, a memory and a communication device at the remote entity to infer that the at least one solar panel has been removed from the array when the first or second signal is interrupted.

10. The method of claim 1, further comprising providing an alarm when the first or second signal is interrupted.

11. The method of claim 1, further comprising communicating the first or the second signal to the remote entity via a communication device being connected to a gateway.

12. The method of claim 1, further comprising communicating the first and the second signal via a panel and an AC outlet.

13. The method of claim 1, further comprising not providing the first and second signal at a commencement of operation;
providing the first signal from the first solar panel to the remote entity only when the second solar panel is removed; and
further comprising inferring that at least one solar panel has been removed from the array when at least one of the first or second signal is communicated to the remote entity.

14. An apparatus for detecting a parameter of a solar panel array, the apparatus comprising:
a first solar panel providing a first signal from the first solar panel to a remote entity;
the first solar panel being connected to a second solar panel;
the second solar panel providing a second signal from the second solar panel to the remote entity; and
a device being connected to the first and the second solar panels, the device inferring that at least one solar panel has been removed from the array when at least one of the first or second signal is interrupted to the device.

15. The apparatus of claim 14, wherein the first and the second solar panel each comprise an inverter.

16. The apparatus of claim 15, wherein each inverter comprises a monitoring circuit to monitor an input of the inverter.

17. The apparatus of claim 16, wherein the monitoring circuit monitors the input of the inverter for at least one of a power signal, a voltage or a current signal.

18. The apparatus of claim 17, wherein the device detects that the input to the respective inverter has been interrupted; and
wherein the device infers that the respective solar panel has been removed.

19. The apparatus claim 18, wherein the device comprises a computing device being connected to the first and the second solar panel, and the computing device inferring that at least one solar panel has been removed from the array when at least one of the first or second signal is interrupted.

20. The apparatus of claim 14, further comprising more than two solar panels with each solar panel providing a respective signal to the device.

21. The apparatus of claim 20, wherein the device infers that at least one solar panel has been removed from the array when at least one signal from the more than two solar panels is interrupted.

22. The apparatus of claim 14, wherein the device comprises a managing system to infer that the at least one solar panel has been removed from the array when the first or second signal is interrupted.

23. The apparatus of claim 14, further comprising an alarm, the device controlling the alarm to provide an indication when the first or second signal is interrupted.

24. The apparatus of claim 14, further comprising a gateway being connected to the device, the gateway communicating the first or the second signal to the device via a communication device being connected to the gateway.

25. The apparatus of claim 14, further comprising communicating the first and the second signal via a panel and an AC outlet.

26. The apparatus of claim 14, further comprising not providing the first and second signal at a commencement of operation; and
providing the first signal from the first solar panel to the device only when the second solar panel is removed; and
further comprising inferring that at least one solar panel has been removed from the array when at least one of the first or second signal is communicated to the device.

27. The apparatus of claim 14, further comprising a gateway being connected to the device, the gateway being connected to a communicator, the communicator being connected to an outlet, the outlet being connected to a panel being connected to a first inverter, which is connected to the first solar panel and further comprising a second inverter being connected to the second solar panel, the second inverter being connected to the first solar panel.

28. A method of safely shutting down operation of a solar panel array comprising:
providing a first solar panel being connected to a first inverter, the first inverter comprising at least one of a control circuit, a power conversion circuit, a monitoring circuit and a communication circuit;
providing a second solar panel being connected to a second inverter, the second inverter comprising at least one of the control circuit, the power conversion circuit, the monitoring circuit and the communication circuit;
providing a managing system being connected to the first and the second solar panels; and
controlling at least one component of the first or the second inverter to shut down operation of the solar panel array.

29. A safety device comprising:
a first solar panel being connected to a first inverter, the first inverter comprising at least one of a control circuit, a power conversion circuit, a monitoring circuit and a communication circuit;
a second solar panel being connected to a second inverter, the second inverter comprising at least one of the control circuit, the power conversion circuit, the monitoring circuit and the communication circuit;
a managing system being connected to the first and the second solar panels; and
the managing system controlling at least one component of the first or the second inverter to shut down operation of the solar panel array.

30. An inverter comprising:
a control circuit, a power conversion circuit, a monitoring circuit and a communication circuit, the communication circuit providing a signal to a remote entity, wherein the remote entity infers a condition when the signal is interrupted.
